(19) United States
(12) Patent Application Publication
(10) Pub. No.: US 2007/0286250 A1
(43) Pub. Date: Dec. 13, 2007

(54) Active layer of laser diode

(75) Inventors: Po-Hsun Lei, Chiayi City (TW); Chyi-Dar Yang, Hsinchu (TW); Jun-Chieh Huang, Hsinchu (TW)

Correspondence Address: TROXELL LAW OFFICE PLLC;SUITE 1404, 5205 LEESBURG PIKE, FALLS CHURCH, VA, 22041, US

(73) Assignee: Po-Hsun Lei

(21) Appl. No.: 11/448,801

(22) Filed: Jun. 8, 2006

(51) Int. Cl. H01S 5/00

(52) U.S. Cl. 372/45.011

(57) ABSTRACT

An active layer of a laser diode comprises: a plurality of quantum well layers; a plurality of quantum barrier layers formed between the quantum well layers; and a plurality of tensile-stressed GaInP layers formed between the quantum barrier layers, whereby the lateral flow of electron-hole pairs in the active layer can be blocked so as to prevent the recombination of the electron-hole pairs in the quantum barrier layers of the laser diode for reducing the carrier current leakage and preventing the tensile-stressed GaInP layers from compensating the compressive-stressed quantum well layers so as to maintain the compressive stress of the quantum well layers.

### FIELD OF THE INVENTION

The present invention relates to an active layer of a laser diode, and more particularly to an active layer having high-energy-gap, tensile-stressed GaInP layers formed between quantum barrier layers, which are formed between quantum well layers, whereby the critical current of the laser diode can be reduced and the optical output power of the laser diode can be increased.

### BACKGROUND OF THE INVENTION

Generally speaking, a 1.3- or 1.55-micrometer laser has been applied to the optical fiber communication or optoelectronic integrated circuit as a signal-emitting terminal. Compared with the 1.55-micrometer laser, the 1.3-micrometer laser provided the advantage of lower chromatic dispersion in the optical fiber communication. However, the loss of strength caused by increasing of transmission distance in the 1.3-micrometer laser was much more serious than that in the 1.55-micrometer laser. Accordingly, the 1.3-micrometer laser was mostly applied to the high-power laser diode.

The conventional laser diode was usually provided with GaInAsP or GaInP quantum well layers. As shown in FIG. 5 and FIG. 6, the active layer B of the conventional laser diode, from bottom to top, was composed of five quantum well layers 10a and four quantum barrier layers 20a stacked one by one. The quantum barrier layer 20a with the low energy-gap was usually suffered from the Auger recombination effect, which affects the luminous power. Besides, the low-energy-gap quantum barrier layer 20a was unable to prevent the lateral flow of the hot-electron current effectively, resulting in the recombination of electron-hole pairs in the quantum barrier layers 20a. Accordingly, this kind of laser diode was unable to reduce the critical current and to increase the optical output power effectively.

Whereas the foregoing deficiency of the active layer of the conventional laser diode, the present inventor makes diligent studies in providing the consumers with an improved active layer of an laser diode.

### SUMMARY OF THE INVENTION

It is a main object of the present invention to provide an active layer having the high-energy-gap, tensile-stressed GaInP layers formed between the quantum barrier layers, whereby the critical current of the laser diode can be reduced and the optical output power of the laser diode can be improved for increasing the operation efficiency of the laser diode.

In order to achieve the above-mentioned objects, an active layer of a laser diode comprises: a plurality of quantum well layers; a plurality of quantum barrier layers formed between the quantum well layers; and a plurality of tensile-stressed GaInP layers formed between the quantum barrier layers, whereby the lateral transport of electron-hole pairs in the active layer can be blocked so as to prevent the recombination of the electron-hole pairs in the quantum barrier layers of the laser diode for reducing the carrier current leakage and preventing the tensile-stressed GaInP layers from compensating the compressive-stressed quantum well layers so as to maintain the compressive stress of the quantum well layers.

The aforementioned objects and advantages of the present invention will be readily clarified in the description of the preferred embodiments and the enclosed drawings of the present invention.

### BRIEF DESCRIPTION OF THE DRAWINGS

FIG. 1 is a plan view showing the active layer of the laser diode of the present invention.

FIG. 2 is a schematic view showing the conduction band of the energy band according to the active layer of the laser diode of the present invention.

FIG. 3 is a three-dimensional view showing the laser diode of the present invention.

FIG. 4 is a plan view showing the laser diode of the present invention.

FIG. 5 is a plan view showing an active layer of a conventional laser diode.

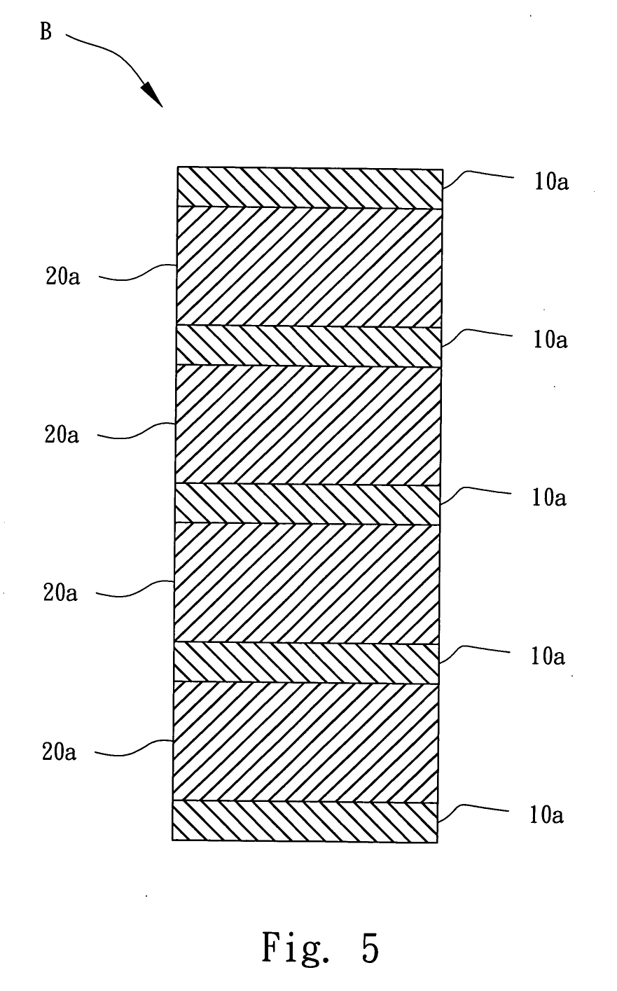

FIG. 6 is a schematic view showing the conduction band of the energy band according to the conventional active layer of the laser diode.

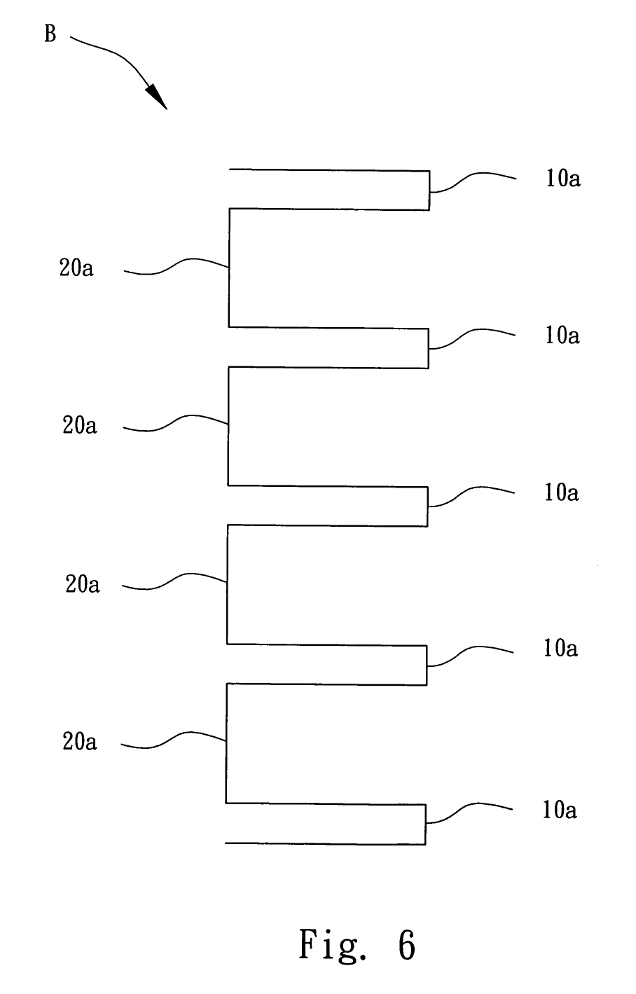

### DETAILED DESCRIPTION OF THE PREFERRED EMBODIMENT

The description taken with the drawings make the structures, features, and embodiments of the present invention apparent to the examiner how the present invention may be embodied in practice.

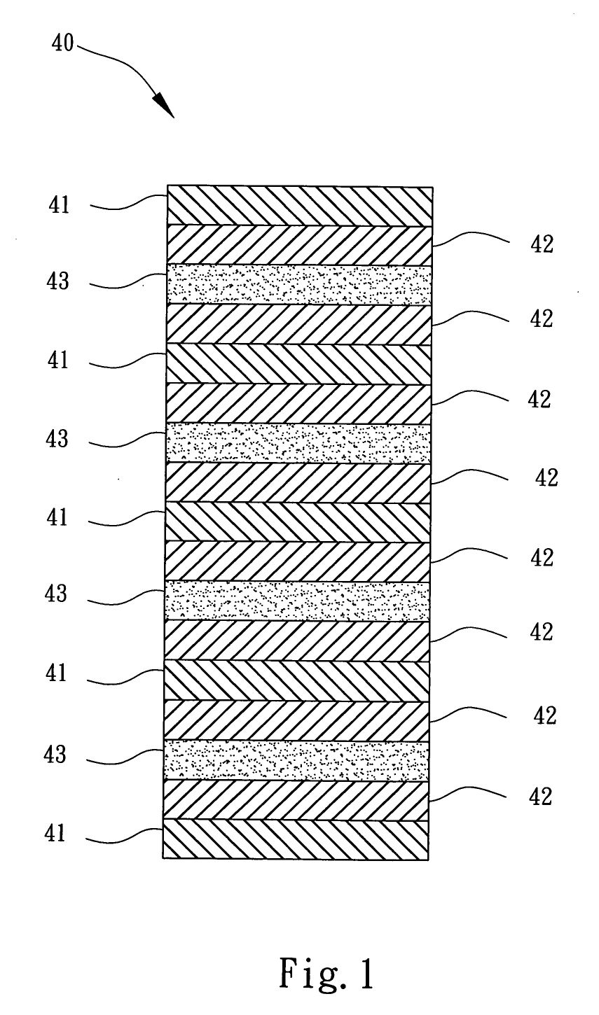

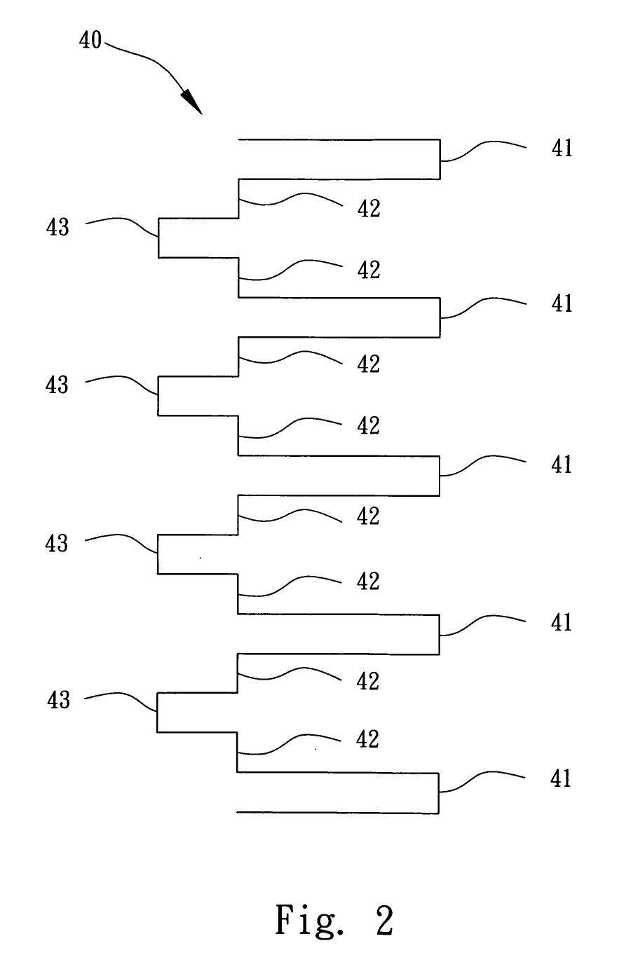

Referring to FIG. 1 and FIG. 2, an active layer 40 of the present invention, from bottom to top, comprises a GaInAsP quantum well layer 41, a GaInAsP quantum barrier layer 42, a GaInP layer 43, a GaInAsP quantum barrier layer 42, a GaInAsP quantum well layer 41, a GaInAsP quantum barrier layer 42, a GaInP layer 43, a GaInAsP quantum barrier layer 42, a GaInAsP quantum well layer 41, a GaInAsP quantum barrier layer 42, a GaInP layer 43, a GaInAsP quantum barrier layer 42, a GaInAsP quantum well layer 41, a GaInAsP quantum barrier layer 42, a GaInP layer 43, a GaInAsP quantum barrier layer 42, and a GaInAsP quantum well layer 41.

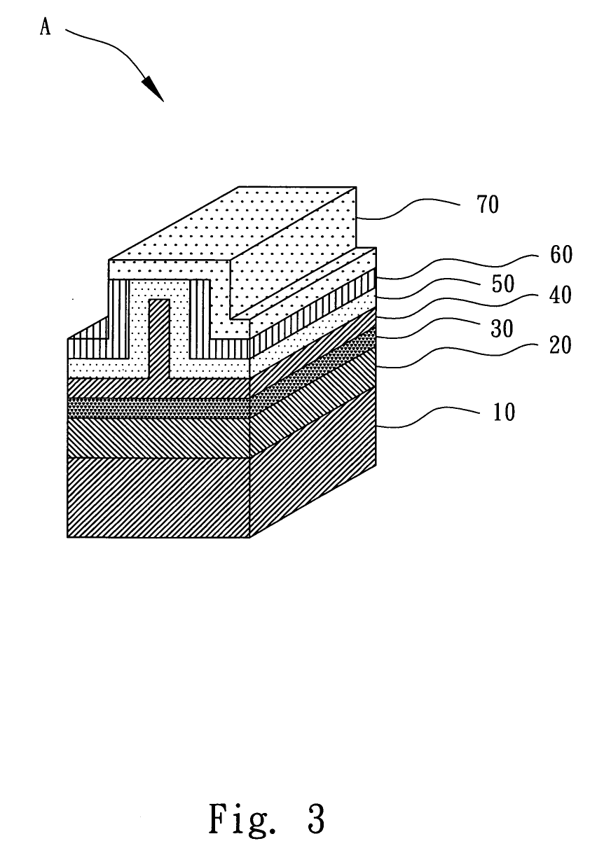

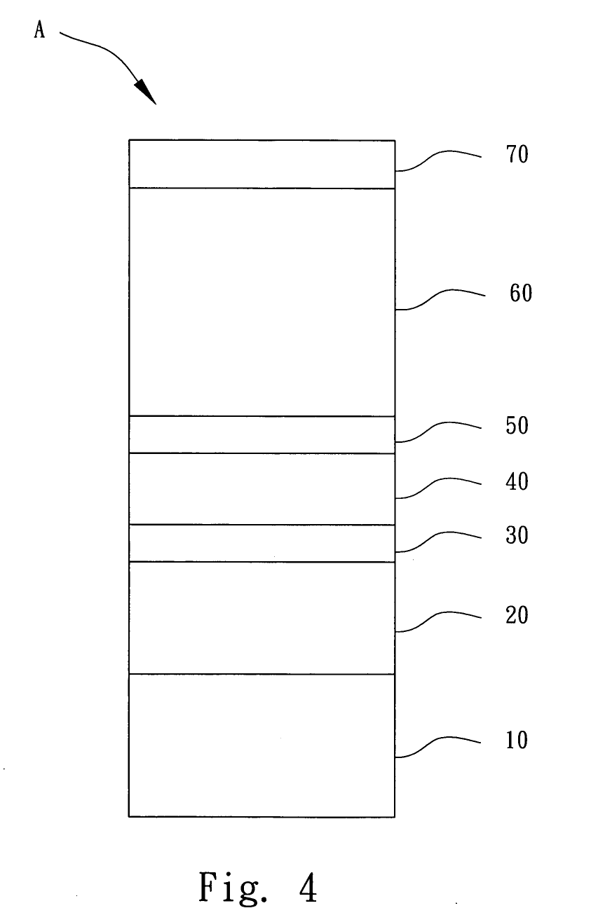

Referring further to FIG. 3 and FIG. 4, a laser diode A, from bottom to top, comprises a n-InP substrate 10, a n-InP cladding layer 20, an i-InGaAsP waveguide layer 30, the active layer 40, an i-InGaAsP waveguide layer 50, a P—InP cladding layer 60, and a P⁺InAsP layer 70.

Referring again to FIG. 1 through FIG. 4, according to the laser diode A of the present invention, the purpose of forming the i-InGaAsP waveguide layer 30 on the n-InP cladding layer 20, which is formed on the n-InP substrate 10, is to confine the optical field to the region of the quantum well layer 41 of the active layer 40 for forming the compressive-stressed quantum well layer 41. The compressive-stressed quantum well layer 41 is able to improve optical and differential gain for further reducing the critical current and increasing the speed and the optical output power. However, the quantum barrier layer 42, which has a low energy gap, cannot prevent the lateral flow of electron-hole pairs, which causes the reducing of the optical output power due to the recombination of the electron-hole pairs in the quantum barrier layer 42. In accordance with the laser diode A of the present invention, the tensile-stressed GaInP layer 43, which has a high energy gap, is formed between two non-stressed quantum barrier layers 42, which are formed between every two adjacent compressive-stressed quantum well layers 41. The utilization of the high-energy-gap, tensile-stressed GaInP layers 43 is an inventive feature of the present invention, wherein the GaInP layers 43 and the non-stressed quantum barrier layers 42 provide two functions. One of which is to prevent the recombination of the electron-hole pairs in the quantum barrier layers 42 of the laser diode A by blocking the lateral flow of the electrons for effectively reducing the hot-electron current and the current leakage, wherein the reducing of the hot-electron current causes the reducing of the critical current and the increasing of the optical output power. The other function of the non-stressed quantum barrier layers 42 is to prevent the GaInP layers 43 from compensating the compressive-stressed quantum well layers 41 so as to improve the optical and differential gain. Thereafter, the i-InGaAsP waveguide layer 50 is formed for confining the optical field. Finally, the P—InP cladding layer 60 and the P⁺InAsP layer 70 are formed in sequence to complete the laser diode A with the spine-shaped waveguide structure.

In accordance with the foregoing description, it is apparent that the present invention provides the advantages as follows:
1. the present invention indeed reduces the critical current and increases the optical output power by forming the high-energy-gap, tensile-stressed GaInP layers between the quantum barrier layers, which are formed between the quantum well layers of the active layer; and
2. the present invention prevents the tensile-stressed GaInP layers from compensating the compressive-stressed quantum well layers so as to improve the optical and differential gain by forming the non-stressed quantum barrier layers between the quantum well layers of the active layer.

In summary, the present invention indeed achieves the expected objects by providing the active layer of the laser diode, which is able to reduce the critical current and increase the optical output power and which is suitable for high temperature operation. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. An active layer of a laser diode comprising:
a plurality of quantum well layers;
a plurality of quantum barrier layers formed between said quantum well layers; and
a plurality of tensile-stressed GaInP layers formed between said quantum barrier layers, whereby the lateral flow of electron-hole pairs in said active layer can be blocked so as to avoid the recombination of the electron-hole pairs in said quantum barrier layers of said laser diode for reducing the carrier current leakage and preventing said tensile-stressed GaInP layers from compensating said compressive-stressed quantum well layers so as to maintain the compressive stress of said quantum well layers.

2. The active layer of the laser diode of claim 1, wherein said active layer, from bottom to top, comprises a first quantum well layer, a first quantum barrier layer, a first GaInP layer, a second quantum barrier layer, a second quantum well layer, a third quantum barrier layer, a second GaInP layer, a fourth quantum barrier layer, a third quantum well layer, a fifth quantum barrier layer, a third GaInP layer, a sixth quantum barrier layer, a fourth quantum well layer, a seventh quantum barrier layer, a fourth GaInP layer, an eighth quantum barrier layer, and a fifth quantum well layer.

3. The active layer of the laser diode of claim 1, wherein said quantum barrier layers are non-stressed GaInAsP quantum barrier layers.

4. The active layer of the laser diode of claim 1, wherein said quantum well layers are compressive-stressed GaInAsP quantum well layers.
